(19) United States
(12) Patent Application Publication
(10) Pub. No.: US 2007/0093068 A1
(43) Pub. Date: Apr. 26, 2007

(54) Manufacturing method of semiconductor device

(75) Inventors: Junji Oh, Kawasaki (JP); Yuka Kase, Kawasaki (JP); Masatoshi Osuki, Kawasaki (JP); Masaomi Yamano, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/446,304

(22) Filed: Jun. 5, 2006

(30) Foreign Application Priority Data
Oct. 25, 2005 (JP) 2005-309769

(51) Int. Cl. H01L 21/302; H01L 21/461

(52) U.S. Cl. 438/704; 438/745

(57) ABSTRACT

A semiconductor device manufacturing method involves heating up a solution containing sulfuric acid and hydrogen peroxide solution, replenishing the solution with a predetermined quantity of sulfuric acid and a predetermined quantity of hydrogen peroxide solution at a predetermined interval, maintaining a concentration of the sulfuric acid in the solution at a predetermined concentration level or higher, immersing the semiconductor substrate in the solution, and cleaning the semiconductor substrate.

### BACKGROUND OF THE INVENTION

The present invention relates to a manufacturing method of a semiconductor device.

Over the recent years, as LSI (Large Scale Integration) has become hyperfine, a gate length of a MOS (Metal Oxide Semiconductor) has decreased. Therefore, a short channel effect becomes conspicuous, with the result that a normal operation of the transistor can not be acquired. Such being the case, a method of forming a source-drain diffusion area with high accuracy is employed for normally operating the transistor. At first, a sidewall spacer is formed along a side surface of a gate electrode. The sidewall spacer uses a film type such as a CVD (Chemical Vapor Deposition) oxide film (which will hereinafter be simply referred to also as an oxide film) and a CVD nitride film (which will hereinafter be simply referred to also as a nitride film). Then, after forming the sidewall spacer along the side surface of the gate electrode, an impurity is ion-implanted, thereby forming a source-drain diffusion area.

Herein, a photoresist film (which will hereinafter be simply called also a resist) is used in the case of the ion-implantation being effected into an extension area of a MOS transistor. Then, the resist is peeled off by employing an SPM (sulfuric acid hydrogen peroxidemixture) solution defined as a mixed solution of concentrated sulfuric acid and hydrogen peroxide solution. Further, after a dry etching process on the occasion of forming the sidewall, the SPM solution is employed for a metal removing process. Thus, the process using the SPM solution is conducted several times in a state where the nitride film forming the sidewall spacer exists on the surface of the semiconductor substrate. Moreover, in a photolithography process, the nitride film is subjected to patterning. In this photolithography process, if a drawback occurs in the pattern at a stage of finishing development, there might be a case, wherein the resist is removed by the SPM solution, and the process is conducted again from resist coating. In this case also, the process using the SPM solution is carried out in a state where a silicon nitride film exists on the surface of the semiconductor substrate. It should be noted that the following Patent document 1 discloses a technology related to a resist stripping in the case of using the nitride film for a capacitor. Further, the following Patent document 2 discloses a technology related to a cleaning method using a mixed solution of the sulfuric acid and the hydrogen peroxide solution.
[Patent document 1]Japanese Patent Application Laid-Open Publication No.2002-76272
[Patent document 2] Japanese Patent Application Laid-Open Publication No.2001-118821

### SUMMARY OF THE INVENTION

The prior arts given above are, however, incapable of restraining the etching, using the SPM solution, of the nitride film formed on the surface of the semiconductor substrate. It is an object of the present invention to restrain the etching, using the SPM solution, of the nitride film formed on the surface of the semiconductor substrate.

The present invention adopts the following means in order to solve the problems given above. Namely, a semiconductor device manufacturing method according to the present invention comprises a step of heating up a solution containing sulfuric acid and hydrogen peroxide solution, a step of replenishing the solution with a predetermined quantity of sulfuric acid and a predetermined quantity of hydrogen peroxide solution at a predetermined interval, a step of maintaining a concentration of the sulfuric acid in the solution at a predetermined concentration level or higher, and a step of immersing a semiconductor substrate in the solution, and cleaning the semiconductor substrate.

According to the present invention, it is possible to restrain the etching, using the SPM solution, of the nitride film formed on the surface of the semiconductor substrate.

### BRIEF DESCRIPTION OF THE DRAWINGS

FIG. 1 is a graphic chart showing a relationship between a concentration of sulfuric acid in an SPM solution and an etching quantity of a nitride film.

FIGS. 2A-2D are sectional views each showing a process of forming an extension area 13 and a pocket area 12 in the semiconductor device manufacturing method in the embodiment.

FIG. 3 is a sectional view of a semiconductor substrate 1 formed with a sidewall oxide film 8.

FIG. 4 is a sectional view of the semiconductor substrate 1 formed with a sidewall nitride film 9.

FIG. 5 is a sectional view of the semiconductor substrate 1 formed with a sidewall spacer 10.

FIG. 6 is a sectional view of the semiconductor substrate 1 formed with a notched sidewall 7.

FIG. 7A is a sectional view of the semiconductor substrate 1 formed with the notched sidewall spacer 7.

FIG. 7B is a sectional view of the semiconductor substrate 1 on which the nMOS area 2 is formed with a source-drain diffusion area 15.

FIG. 7C is a sectional view of the semiconductor substrate 1 on which the pMOS area 3 is formed with the source-drain diffusion area 15.

FIG. 7D is a sectional view of the semiconductor substrate 1 formed with the nMOS transistor 17 and the pMOS transistor 18.

FIGS. 8A-8E are sectional views of the photolithography process in the semiconductor device manufacturing method according to the embodiment.

FIG. 9 is a diagram of a configuration of a device in the embodiment.

FIG. 10 is a process flowchart of the device in the embodiment.

FIG. 11 is a process flowchart of exchanging the SPM solution in an internal tank 121 in the device according to the embodiment.

FIG. 12 is a graphic chart showing a relationship between a life-time of the SPM solution and an etching quantity of the nitride film.

### DETAILED DESCRIPTION OF THE INVENTION

A detection method according to a best mode (which will hereinafter be referred to as an embodiment) for carrying out the present invention will hereinafter be described with reference to the drawings. Configurations in the following embodiments are exemplifications, and the present invention is not limited to the configurations in the embodiments.

<Substance of the Invention>

A resist peeling method using an SPM solution will hereinafter be explained. To begin with, sulfuric acid is mixed with hydrogen peroxide solution. Next, as expressed in the following formula (1), active oxygen is produced by exothermic reaction.
H2SO4+H2O2→H2SO4+H2O+O (1)
Then, as expressed in the following formula (2), peroxomonosulfuric acid (H2SO5) is produced.
H2SO4+H2O2→H2SO5+H2O (2)
The peroxomonosulfuric acid produces the active oxygen by reacting with H20 as expressed in the following formula (3).
H2SO5+H2O→H2SO4+H2O+O (3)
Further, as expressed in the following formula (4) peroxodisulfuric acid (H2S2O8) is produced by mixing the sulfuric acid with the hydrogen peroxide solution. The peroxodisulfuric acid acts as an oxidant.
2H2SO4+H2O2→H2S2O8+2H2O (4)
The peroxodisulfuric acid produces the active oxygen by reacting with H20 as expressed in the following formula (5).
H2S2O8+H2O→2H2SO4+O (5)
The active oxygen is produced by the reaction described above, and the resist classified as an organic matter is decomposed by the active oxygen etc. Further, organic fine particles referred to simply as particles and metal impurities, which are adhered to a semiconductor substrate, are removed by cleaning that involves employing the SPM solution.

The hydrogen peroxide solution in the SPM solution is consumed and turns out to be water when decomposing the resist. Moreover, the SPM solution has a high temperature, and the hydrogen peroxide solution in the SPM solution is decomposed to the water and the oxygen. Therefore, due to a decrease in concentration of the hydrogen peroxide in the SPM solution, a resist peeling capacity declines. For preventing the decline of the resist peeling capacity, the SPM solution is replenished with the hydrogen peroxide solution at an interval of a fixed period of time, whereby the resist peeling capacity can be maintained.

This being the case, the SPM solution is replenished with the hydrogen peroxide solution. In the case of the replenishing the SPM solution with the hydrogen peroxide solution, concentration of the sulfuric acid decreases as the time elapses. If a sidewall spacer formed by a nitride film exists on the surface of the semiconductor substrate, the nitride film of the sidewall spacer is etched by effecting a process using the SPM solution.

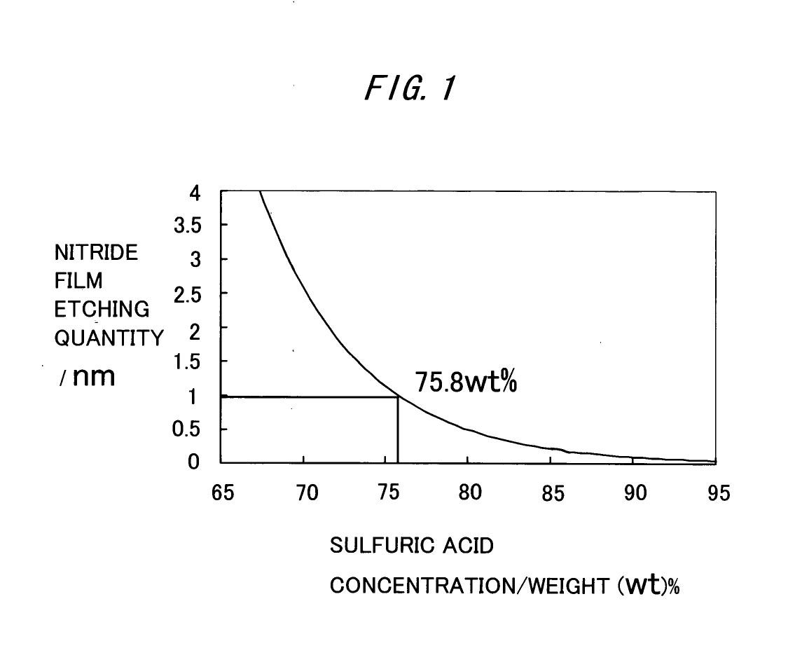

FIG. 1 is a graphic chart showing a relationship between the concentration of the sulfuric acid in the SPM solution and a nitride film etching quantity. As shown in FIG. 1, if the concentration of the sulfuric acid in the SPM solution rises, the etching quantity of the nitride film decreases. While on the other hand, if the concentration of the sulfuric acid in the SPM solution decreases, the etching quantity of the nitride film rises. Thus, the etching quantity of the nitride film by the SPM solution changes depending on the concentration of the sulfuric acid in the SPM solution. Namely, in the case of executing the process employing the SPM solution in a state where the concentration of the sulfuric acid in the SPM solution rises, the etching of the nitride film of the sidewall spacer is restrained. While on the other hand, in the case of executing the process employing the SPM solution in a state where the concentration of the sulfuric acid in the SPM solution decreases, the etching of the nitride film of the sidewall spacer is advanced.

Accordingly, there occurs a scatter in film thickness of the sidewall spacer in the concentration-increasing-case of the sulfuric acid in the SPM solution and in the concentration-decreasing-case thereof. The scatter in the film thickness of the sidewall spacer affects formation of a source-drain diffusion area on the semiconductor substrate. To be specific, the scatter occurs in a lateral direction in the source-drain diffusion area, and there is a scatter in a depletion layer with respect to a gate (electrode) width, thereby causing occurrence of a scatter in performance of a transistor. Further, when patterning the nitride film once again, the SPM solution is employed for peeling off the resist. In the case of repeating this pattering of the nitride film several times, the thickness of the nitride film decreases. The decrease in the thickness of the nitride film becomes a cause of being unable to form the nitride film by patterning.

In the embodiment, in a process of performing the resist peeling process or the cleaning process of the semiconductor substrate by using the SPM solution, the SPM solution is replenished with the sulfuric acid and the hydrogen peroxide solution at the predetermined interval. The concentration of the sulfuric acid in the SPM solution is maintained at the predetermined level (concentration) by replenishing the SPM solution with the sulfuric acid and the hydrogen peroxide solution. The concentration of the sulfuric acid in the SPM solution is maintained at the predetermined level, thereby making it possible to restrain the etching of the nitride film formed on the semiconductor substrate by use of the SPM solution. For maintaining the capacity, essentially based on the SPM solution, of removing the organic matter and particles, an upper limit of the concentration of the sulfuric acid may be set on the order of approximately 97.4%.

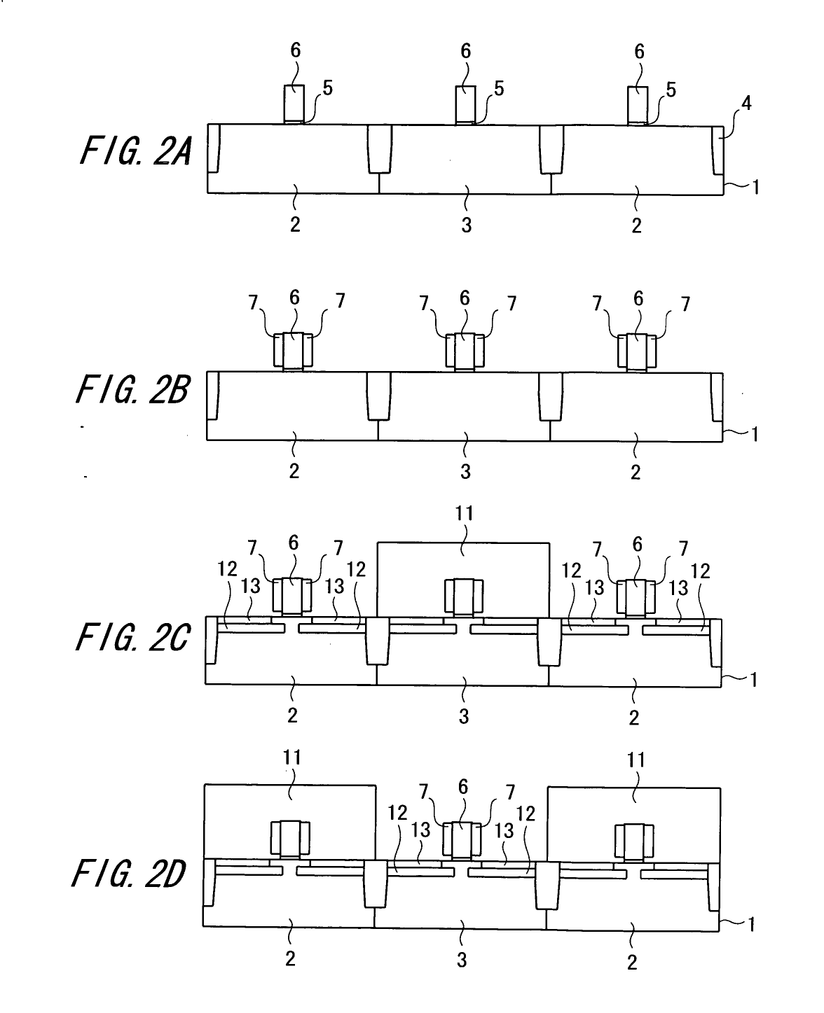

A method of manufacturing a semiconductor device in the embodiment will hereinafter be described with reference to the drawings. FIGS. 2A-2B are sectional views each showing a process of forming an extension area 13 and a pocket area 12 in the semiconductor device manufacturing method in the embodiment. As shown in FIG. 2A, a semiconductor substrate 1 is formed with an nMOS area 2 and a pMOS area 3. Further, the semiconductor substrate 1 is formed with an element separation area 4. Moreover, a gate insulating film 5 is formed on the surface of the semiconductor substrate 1. Then, a gate electrode 6 is formed on the gate insulating film 5.

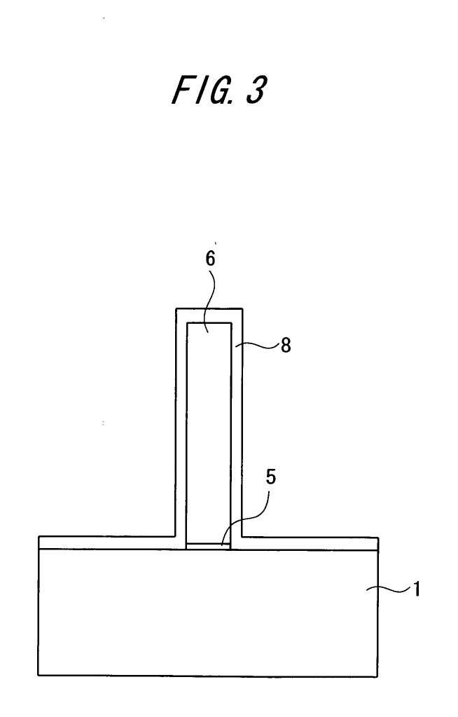

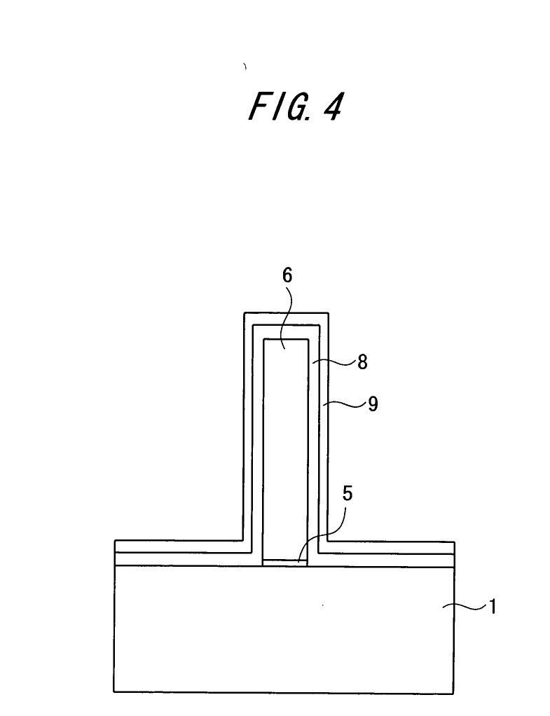

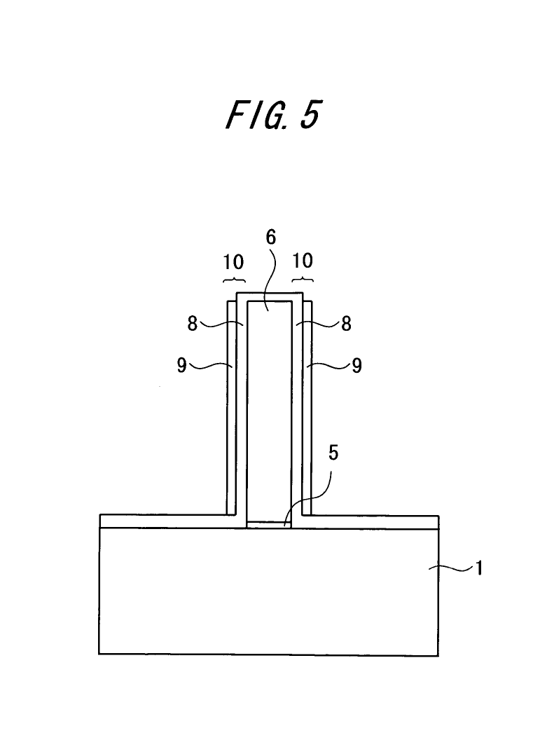

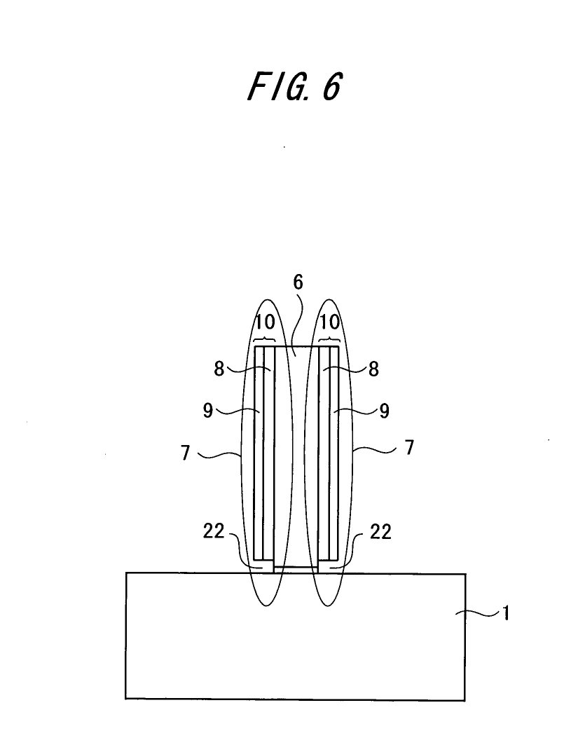

Next, as illustrated in FIG. 2B, a notched sidewall spacer 7 is formed along the side surface of the gate electrode 6 provided on the semiconductor substrate 1. A process of forming the notched sidewall spacer 7 on the semiconductor substrate 1 will hereinafter be described with reference to FIGS. 3 through 6. FIG. 3 is a sectional view of the semiconductor substrate 1 formed with a sidewall oxide film 8. FIG. 4 is a sectional view of the semiconductor substrate 1 formed with a sidewall nitride film 9. FIG. 5 is a sectional view of the semiconductor substrate 1 formed with a sidewall spacer 10. FIG. 6 is a sectional view of the semiconductor substrate 1 formed with the notched sidewall spacer 7.

To start with, as shown in FIG. 3, for example, the sidewall oxide film 8 having a thickness of 15 nm is formed on the gate electrode 6 and on the semiconductor substrate 1 by a low-pressure CVD (Chemical Vapor Deposition) method involving the use of TEOS (Tetra Ethyl Ortho Silicate) as a source. Then, as illustrated in FIG. 4, the sidewall nitride film 9 having a thickness of, e.g. 5 nm is formed on the sidewall oxide film 8 by the CVD method involving the use of silane (SiH₄) and ammonium (NH₃). Next, anisotropic etching is effected over an upper surface of the semiconductor substrate 1 approximately in the vertical direction. As illustrated in FIG. 5, the sidewall nitride film 9 can be left along the sidewall of the gate electrode 6 by the anisotropic etching.

Thus, the sidewall spacer 10 is formed on the side surface of the gate electrode 6. Then, after the anisotropic etching, a process employing the SPM solution is conducted for removing the metal impurities such as Na and Al adhered to the surface of the semiconductor substrate 1. The process employing the SPM solution is carried out in a way that immerses the semiconductor substrate 1 into the SPM solution. Further, the sidewall oxide film 8 is wet-etched, wherein the sidewall nitride film 9 is used as a mask. The wet-etching is conducted by using an oxide film etching solution such as a HF (Hydrogen Fluoride) solution and a BHF (Buffered Hydrogen Fluoride) solution. As shown in FIG. 6, the notched sidewall spacer 7 is formed by the wet-etching. It should be noted that the sidewall nitride film has properties such as a film density and a stress that differ depending on a film forming condition and a type of gas used for reaction. Further, a proper concentration of the SPM solution is determined depending on each film quality.

Next, a process of forming the pocket area 12 and the extension area 13 in the nMOS area 2 will be explained. As shown in FIG. 2C, the pocket area 12 is formed in the nMOS area 2 by using, as masks, the gate electrode 6 formed with the notched sidewall spacer 7 and a resist pattern 11 covering the pMOS area 3. In the case of forming the pocket area 12 in the nMOS area 2, the ion-implantation is effected by use of, e.g., indium or boron.

Then, as shown in FIG. 2C, the extension area 13 is formed in the nMOS area 2 by using, as masks, the gate electrode 6 formed with the notched sidewall spacer 7 and the resist pattern 11 covering the pMOS area 3 . In the case of forming the extension area 13 in the nMOS area 2, the ion-implantation is performed by using, e.g., arsenic.

Further, after forming the pocket area 12 and the extension area 13 in the nMOS area 2, the resist pattern 11 covering the pMOS area 3 is peeled off. The stripping of the resist pattern 11 involves effecting an ashing process of the resist pattern 11 by use of an O₂ gas, a CF₄ gas and a forming gas. Alternatively, the stripping of the resist pattern 11 involves effecting the ashing process of the resist pattern 11 by use of only the O₂ gas. This ashing process is executed under an optimized ashing process condition. Then, a wet-process is carried out for removing the ashed resist pattern 11. In the wet-process, the resist pattern 11 is peeled off by employing the SPM solution.

Next, the process of forming the pocket area 12 and the extension area 13 in the pMOS area 3 will be explained. As shown in FIG. 2D, the pocket area 12 is formed in the pMOS area 3 by using, as masks, the gate electrode 6 formed with the notched sidewall spacer 7 and the resist pattern 11 covering the nMOS area 2. In the case of forming the pocket area 12 in the pMOS area 3, the ion-implantation is conducted by use of, e.g., antimony.

Then, as shown in FIG. 2D, the extension area 13 is formed in the pMOS area 3 by using, as masks, the gate electrode 6 formed with the notched sidewall spacer 7 and the resist pattern 11 covering the nMOS area 2. In the case of forming the extension area 13 in the PMOS area 3, the ion-implantation is conducted by use of, e.g., boron.

Moreover, after forming the pocket area 12 and the extension area 13 in the PMOS area 3, the resist pattern 11 covering the nMOS area 2 is peeled off. The stripping of the resist pattern 11 is the same as the process of peeling off the resist pattern 11 covering the pMOS area 3, which has been explained referring to FIG. 2C.

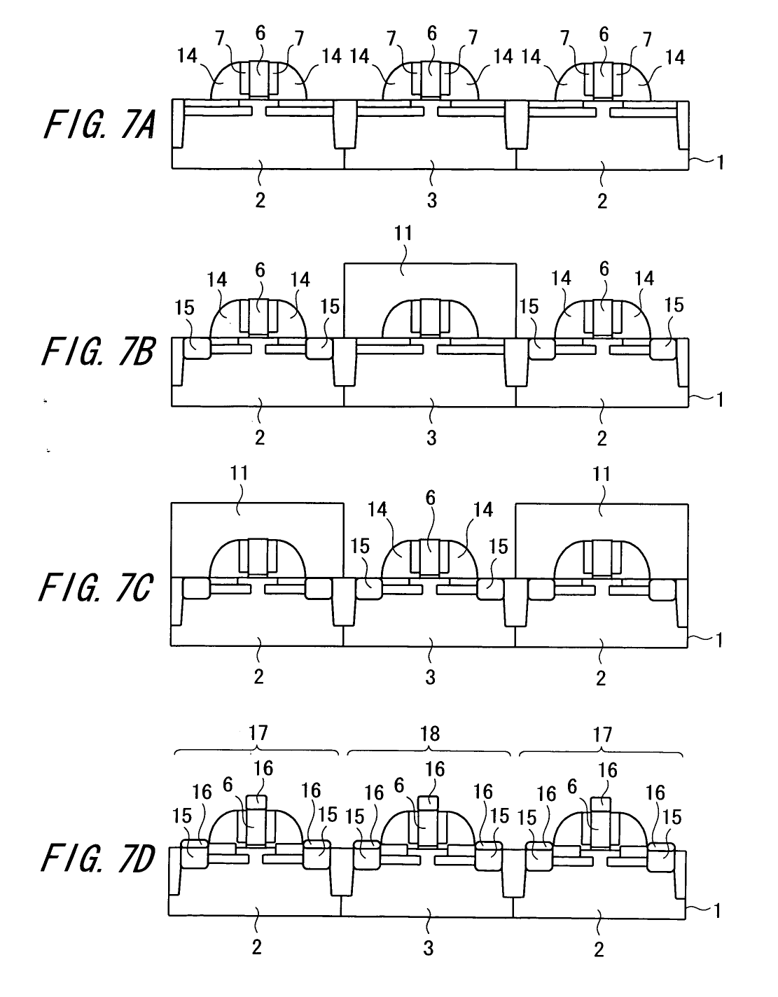

Next, a process of forming an nMOS transistor 17 and a pMOS transistor 18 on the semiconductor substrate 1, will be described with reference to FIGS. 7A-7D. FIG. 7A is a sectional view of the semiconductor substrate 1 formed with the notched sidewall spacer 7. FIG. 7B is a sectional view of the semiconductor substrate 1 in which the nMOS area 2 is formed with a source-drain diffusion area 15. FIG. 7C is a sectional view of the semiconductor substrate 1 in which the pMOS area 3 is formed with the source-drain diffusion area 15. FIG. 7D is a sectional view of the semiconductor substrate 1 formed with the nMOS transistor 17 and the pMOS transistor 18.

To begin with, as shown in FIG. 7A, a sidewall 14 is formed along the side surface of the notched sidewall spacer 7. For instance, an oxide film is deposited on the surface of the notched sidewall spacer 7 formed on the surface of the semiconductor substrate 1 and along the side surface of the gate electrode 6, and the anisotropic etching is effected thereon, thus forming a sidewall 14.

Then, as shown in FIG. 7B, the source-drain diffusion area 15 is formed in the nMOS area 2 by using, as masks, the gate electrode 6 after being formed with the sidewall 14 and the resist pattern 11 covering the pMOS area 3. In the case of forming the source-drain diffusion area 15 in the nMOS area 2, the ion-implantation is conducted by using, e.g., phosphorus.

Next, as shown in FIG. 7C, the source-drain diffusion area 15 is formed in the pMOS area 3 by using, as masks, the gate electrode 6 after being formed with the sidewall 14 and the resist pattern 11 covering the nMOS area 2. In the case of forming the source-drain diffusion area 15 in the pMOS area 3, the ion-implantation is conducted by using, e.g., boron.

Further, as shown in FIG. 7D, a silicide 16 is formed on the gate electrode 6 and on the source-drain diffusion area 15. For instance, the formation of the silicide 16 involves annealing (thermal process) after forming a film of cobalt by sputtering. Thus, the nMOS transistor 17 and the PMOS transistor 18 are formed on the semiconductor substrate 1.

According to the semiconductor device manufacturing method in the embodiment, the etching using the SPM solution for the nitride film can be restrained, and the film thickness of the notched sidewall spacer 7 can be uniformized. The uniformization of the film thickness of the notched sidewall spacer 7 enables the source-drain diffusion area 15 to be formed in the predetermined position in the semiconductor substrate 1. To be specific, the scatter in the performance of the transistor can be restrained by restraining the scatter in the source-drain diffusion area in the lateral direction on the semiconductor substrate. For example, it is feasible to manufacture the transistor that restrains a scatter in electric current flowing through between the source and the drain.

In the embodiment, it is possible to restrain the etching using the SPM solution for the nitride film of the notched sidewall spacer 7 formed on the semiconductor substrate 1. In the embodiment, a notch 22 is formed in the notched sidewall spacer 7. If the notch 22 is not formed in the notched sidewall spacer 7, however, the semiconductor device manufacturing method according to the embodiment can be also applied. To be specific, even in such a case that the semiconductor substrate 1 formed with a sidewall spacer 10 formed with none of the notch 22 is cleaned by the SPM solution, the nitride film of the sidewall spacer 10 can be restrained from being etched by use of the SPM solution.

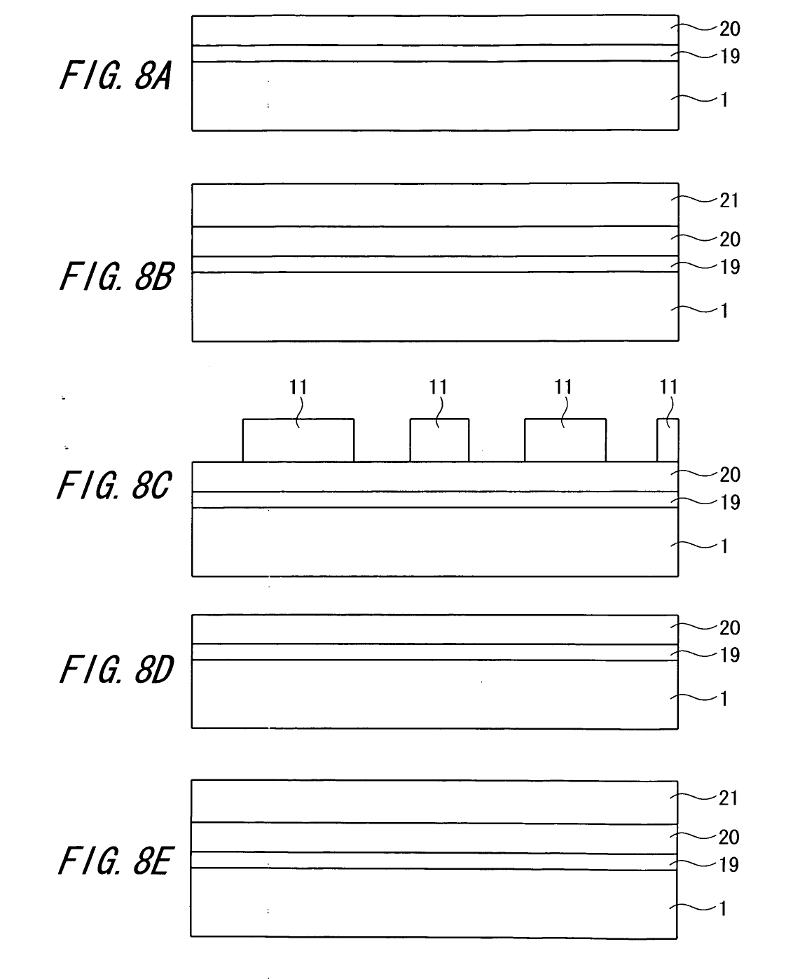

Given below is an explanation of how the resist is removed in a photolithography process in the semiconductor device manufacturing method according to the embodiment. FIGS. 8A-8E are sectional views of the photolithography process in the semiconductor device manufacturing method according to the embodiment.

To begin with, as shown in FIG. 8A, a thermal oxide film 19 is grown on the semiconductor substrate 1. Then, a CVD-nitride film 20 is grown on the thermal oxide film 19. For example, the thermal oxide film 19 is grown by thermal oxidation. Moreover, for instance, the CVD-nitride film 20 is grown by the CVD. Then, as shown in FIG. 8B, a resist film 21 is coated on the CVD-nitride film 20. Next, as shown in FIG. 8C, the resist film 21 is opened by the photolithography process, thereby forming the resist pattern 11. When forming this resist pattern 11, there might be a case in which the resist pattern 11 does not have a desired dimension. In this case, it is required that the patterning be redone once again. As shown in FIG. 8D, the redoing of the patterning involves executing the resist peeling process using the SPM solution and removing the resist pattern 11. Then, as shown in FIG. 8E, the resist film 21 is coated again on the CVD-nitride film 20. If the resist pattern 11 does not gain the desired dimension, the patterning is repeatedly redone over and over again. The CVD-nitride film 20 grown on the semiconductor substrate 1 is etched by the SPM solution in the way that the patterning is repeatedly redone over and over again.

According to the embodiment, on the occasion of removing the resist by the photolithography process, the nitride film can be restrained from being etched by the SPM solution. If the redoing of the patterning occurs, i.e., even the redoing of removing the resist occurs, the nitride film can be restrained from being etched by the SPM solution. It is therefore feasible to provide the manufacturing method of the semiconductor device that does not affect anything when the patterning formation.

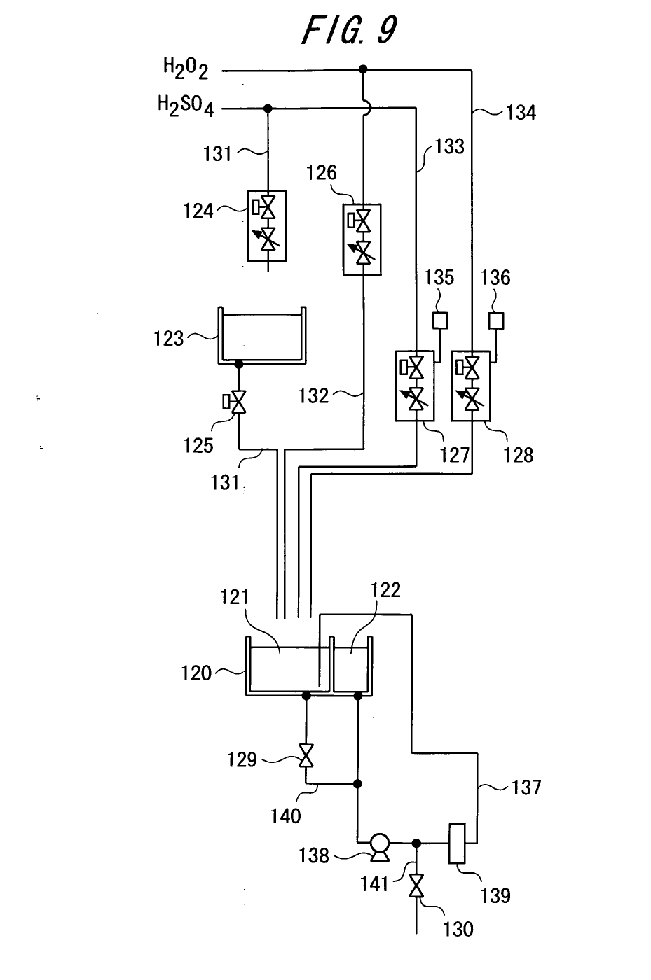

FIG. 9 is a diagram of a configuration of a device (which will hereinafter be referred to as the device in the embodiment) employed for the semiconductor device manufacturing method in the embodiment. In FIG. 9, a process tank 120 is a liquid tank containing the SPM solution composed of a mixture liquid of the sulfuric acid and the hydrogen peroxide. The process tank 120 has an internal tank 121 and an external tank 122. The semiconductor substrate 1 is immersed in the internal tank 121, thus cleaning the semiconductor substrate 1. In the case of immersing the semiconductor substrate 1 in the internal tank 121, the SPM solution overflowing from the internal tank 121 is reserved in the external tank 122.

An SPM preparatory tank 123 is a liquid tank for warming up the sulfuric acid to be inputted into the internal tank 121. A valve 124 is a valve provided in a sulfuric acid input pipe 131 for inputting the sulfuric acid into the SPM preparatory tank 123. The sulfuric acid is inputted into the SPM preparatory tank 123 by opening the valve 124. A valve 125 is a valve provided in the sulfuric acid input pipe 131 for inputting the sulfuric acid into the internal tank 121 from the SPM preparatory tank 123. The sulfuric acid is inputted into the internal tank 121 by opening the valve 125. A valve 126 is a valve provided in a hydrogen peroxide solution input pipe 132 for inputting the hydrogen peroxide solution into the internal tank 121. A valve 127 is a valve provided in a sulfuric acid replenishment pipe 133 for replenishing the internal tank 121 with the sulfuric acid. A valve 128 is a valve provided in a hydrogen peroxide solution replenishment pipe 134 for replenishing the internal tank 121 with the hydrogen peroxide solution. The valve 127 and the valve 128 are provided with timers 135 and 136. The timer 135 controls the valve 127 to open and close for replenishing the internal tank 121 with the sulfuric acid at a predetermined interval. The timer 136 controls the valve 128 to open and close for replenishing the internal tank 121 with the hydrogen peroxide solution at a predetermined interval. When the opening the valve 127 and the valve 128, the sulfuric acid and the hydrogen peroxide solution are inputted into the internal tank 121.

A circulation pipe 137 is a pipe for circulating the SPM solution. The circulation pipe 137 serves to flow 17. the SPM solution reserved in the external tank 122 back into the internal tank 121. The circulation pipe 137 is provided with a pump 138 and a filter 139. The pump 138 serves to circulate the SPM solution from through the external tank 122 into through the internal tank 121. The filter 139 captures dusts in the SPM solution flowing via the circulation pipe 137. A pipe 140 leading to the circulation pipe 137 is provided at a bottom portion of the internal tank 121. Further, the pipe 140 is provided with a valve 129. The valve 129 is normally closed but is opened when discharging the SPM solution in the internal tank 121. When the valve 129 is opened, the SPM solution in the internal tank 121 flows to the circulation pipe 137. Further, for discharging the SPM solution, the circulation pipe 137 is provided with a discharge pipe 141. Further, the discharge pipe 141 is provided with a discharge valve 130. The SPM solution in the internal tank 121 and the SPM solution in the external tank 122 are discharged via the discharge pipe 141 by opening the valve 129 and the discharge valve 130.

An operation of the device in the embodiment will be explained with reference to FIG. 9. In an initial state, the internal tank 121 is in an empty state. At first, when the device in the embodiment is started up, the sulfuric acid and the hydrogen peroxide solution are inputted into the internal tank 121. The sulfuric acid and the hydrogen peroxide solution are inputted into the internal tank 121 by opening the valves 124, 125 and 126. Upon opening the valve 124, the sulfuric acid is inputted into the SPM preparatory tank 123. The sulfuric acid inputted into the SPM preparatory tank 123 is warmed up in the SPM preparatory tank 123. Then, when the valve 125 is opened, the sulfuric acid warmed up in the SPM preparatory tank 123 is inputted into the internal tank 121. Further, when the valve 126 is opened, the hydrogen peroxide solution is inputted into the internal tank 121. The concentrated sulfuric acid is mixed with the hydrogen peroxide solution in the internal tank 121, thereby becoming the SPM solution. In the embodiment, SPM solution is acquired by mixing the concentrated sulfuric acid with the hydrogen peroxide solution at a ratio of 9:1.

Then, the semiconductor substrate 1 is immersed in the internal tank 121 filled with this SPM solution, wherein the resist is peeled off, and so on. Moreover, the SPM solution is heated up at, for example, 135° C. Furthermore, the SPM solution is used while being circulated for a period of 720 min through 2880 min. Generally, at a point of time when the SPM solution is used in circulation over 720 min through 2880 min, the SPM solution is exchanged. Herein, the time when the SPM solution should be exchanged is called a life-time. In the embodiment, the SPM solution is exchanged at a point of time when the SPM solution is used in circulation over 2000 min. According to the semiconductor device manufacturing method in the embodiment, the internal tank 121 is replenished with a predetermined quantity of concentrated sulfuric acid and a predetermined quantity of hydrogen peroxide solution at an interval of a predetermined period of time. The interval of the predetermined period of time is set such as once per 10 min. Then, if necessary, before the semiconductor substrate 1 is inputted into the internal tank 121, the internal tank 121 is replenished with the predetermined quantity of concentrated sulfuric acid and the predetermined quantity of hydrogen peroxide solution.

In the initial state, for instance, the 98% concentrated sulfuric acid having 27L and the 31% hydrogen peroxide solution having 3L are inputted into the internal tank 121. The concentrated sulfuric acid is mixed with the hydrogen peroxide solution in the internal tank 121, thereby becoming the SPM solution. Then, the SPM solution is heated up. Next, after 10 min since the heat-up of the SPM solution has been started, the internal tank 121 is replenished with the 98% concentrated sulfuric acid having 270 mL and the 31% hydrogen peroxide solution having 30 mL. The internal tank 121 is replenished with the concentrated sulfuric acid and the hydrogen peroxide solution by opening the valve 127 and the valve 128.

Further, if necessary, for instance, before the semiconductor substrate 1 is inputted into the internal tank 121, the internal tank 121 is replenished with the 98% concentrated sulfuric acid having 135 mL and the 31% hydrogen peroxide solution having 15 mL. Before the semiconductor substrate 1 is inputted into the internal tank 121, the replenishment of the concentrated sulfuric acid and the hydrogen peroxide solution is performed by opening the valve 127 and the valve 128.

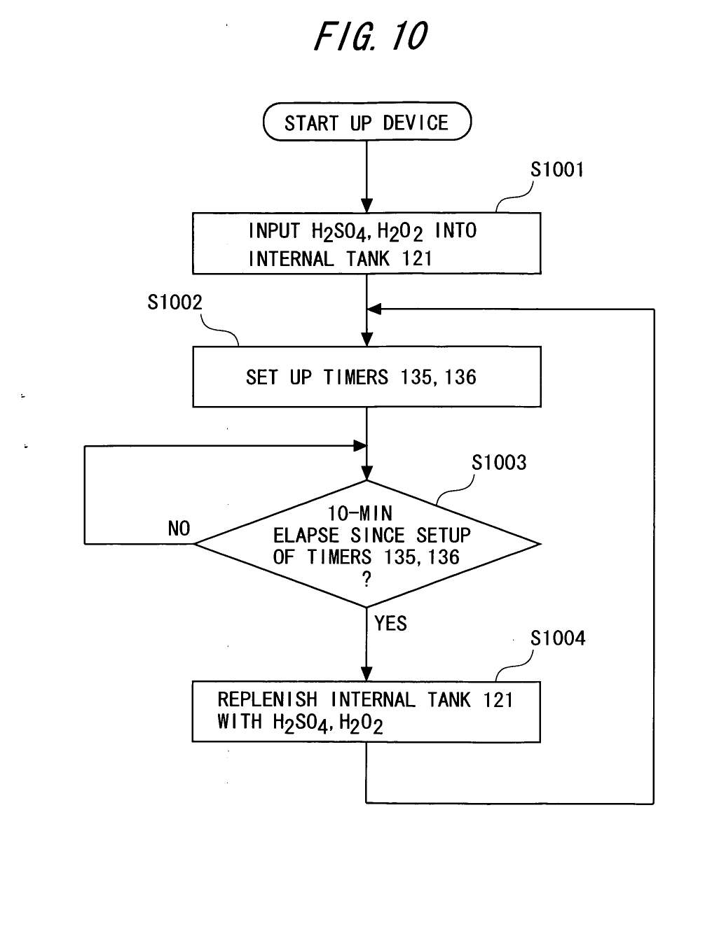

FIG. 10 is a process flowchart of the device in the embodiment. To start with, the device in the embodiment is started up (S1001) . Then, the sulfuric acid and the hydrogen peroxide solution are inputted into the internal tank 121 (S1002). Next, the timers 135 and 136 are set up. For example, the setup time of each of the timers 135, 136 shall be 10 min. The setup time of each of the timers 135, 136 can be set without any restriction. Then, the semiconductor substrate 1 is inputted into the internal tank 121, and the resist peeling process or the cleaning process of the semiconductor substrate 1 is conducted by use of the SPM solution. Next, it is judged whether or not 10 min elapses since the timers 135 and 136 have been set up (S1003) . In the case of a 10-min elapse since the timers 135 and 136 have been set up, the internal tank 121 is replenished with the sulfuric acid and the hydrogen peroxide solution (S1004). While on the other hand, if 10 min does not yet elapse since the timers 135 and 136 have been set up, the process in S1003 is conducted. When the process in S1004 is conducted, the process in S1002 is again effected.

The resist peeling process or the cleaning process of the semiconductor substrate 1 is performed after inputting the sulfuric acid and the hydrogen peroxide solution into the internal tank 121 and setting up the timers 135, 136. Under the state of replenishing the internal tank 121 with the sulfuric acid and the hydrogen peroxide solution, the resist peeling process or the cleaning process of the semiconductor substrate 1 is carried out. In the case of performing the resist peeling process of the semiconductor substrate 1, the resist remaining on the semiconductor substrate 1 is removed by employing a solution obtained by mixing ammonia water, the hydrogen peroxide solution and pure water.

Thus, the device in the embodiment, after the 10-min elapse since the timers 135 and 136 have been set up, conducts the process of replenishing the internal tank 121 with the sulfuric acid and the hydrogen peroxide solution. The internal tank 121 is replenished with the sulfuric acid and the hydrogen peroxide solution, thereby enabling the concentration of the SPM solution to be kept at a concentration level suited to the resist peeling process. Further, the nitride film can be restrained from being excessively etched by the SPM solution. Namely, the etching of the nitride film can be restrained while maintaining the resist peeling capacity of the SPM solution. Moreover, the internal tank 121 is replenished with the sulfuric acid and the hydrogen peroxide solution, thereby enabling the concentration of the SPM solution to be kept at a concentration level suited to the cleaning process of the semiconductor substrate 1. Namely, the etching of the nitride film can be restrained while maintaining the cleaning capacity of the SPM solution.

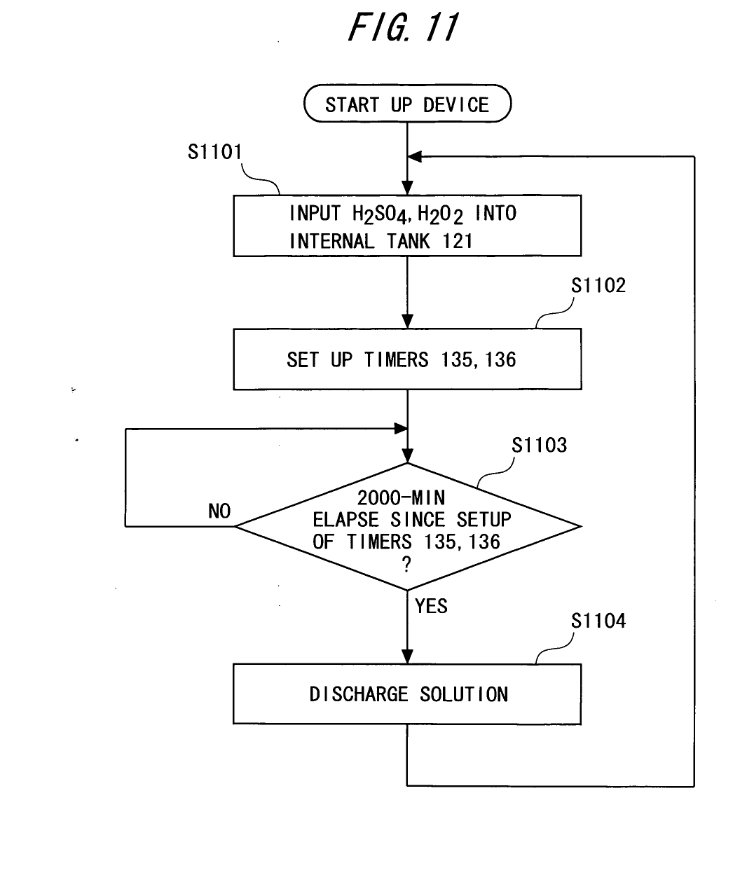

FIG. 11 is a flowchart of a process for exchanging the SPM solution in the internal tank 121 in the device according to the embodiment. To begin with, the device in the embodiment is started up (S1101). Then, the sulfuric acid and the hydrogen peroxide solution are inputted into the internal tank 121 (S1102). Next, the timers 135 and 136 are set up. For example, the setup time of each of the timers 135, 136 shall be 2000 min. The setup time of each of the timers 135, 136 can be set without any restriction.

Then, the semiconductor substrate 1 is inputted into the internal tank 121, and the cleaning process of the semiconductor substrate 1 is performed by using the SPM solution. Next, it is judged whether or not 2000 min elapses since the timers 135 and 136 have been set up (S1103). In the case of a 2000-min elapse since the timers 135 and 136 have been set up, the semiconductor substrate 1 stops being inputted into the internal tank 121. Then, the SPM solution reserved in the internal tank 121 and in the external tank 122 is discharged (S1104). Whereas if the period of 2000 min does not elapse since the timers 135 and 136 have been set up, the process in S1103 is conducted. In the case of effecting the process in S1104, the process in S1102 is again carried out.

A period of time for which the semiconductor substrate 1 is kept immersing in the internal tank 121 in the device according to the embodiment is set to 20 min. For instance, the semiconductor substrate 1 may be immersed for 20 min in the single internal tank 121 and may also be immersed for 10 min in each of the two internal tanks 121. As shown in FIG. 1, if a concentration of the sulfuric acid in the SPM solution is equal to or larger than 75.5% by mass (wt) , an etching quantity of the nitride film is equal to or smaller than 1 nm. Accordingly, if the concentration of the sulfuric acid in the SPM solution in the internal tank 121 is kept equal to or larger than 75.8% by mass, a fluctuation in characteristic of the semiconductor substrate 1 can be restrained. Further, a performance-stabilized transistor can be formed by restraining the fluctuation in characteristic of the semiconductor substrate 1.

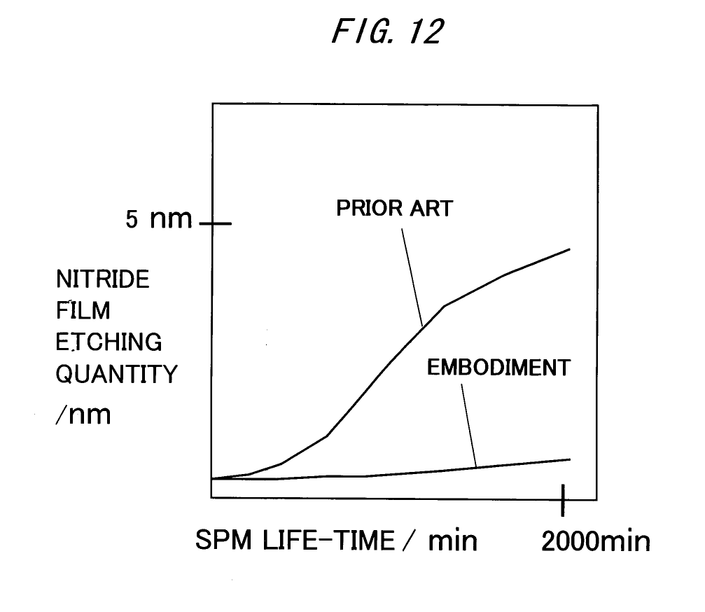

FIG. 12 is a graphic chart showing a relationship between the life-time of the SPM solution and the etching quantity of the nitride film. According to the prior art, the internal tank 121 is replenished with the 32% hydrogen peroxide solution having 65 mL once for every 4 min. According to the semiconductor device manufacturing method in the embodiment, the internal tank 121 is replenished with the 98% concentrated sulfuric acid having 270 mL and the 32% hydrogen peroxide solution having 30 mL once for every 10 min. According to the semiconductor device manufacturing method in the embodiment, even after the 2000-min elapse of the life-time, the etching quantity of the nitride film is equal to or smaller than 1 nm. While on the other hand, according to the prior art, at a point of the time when 2000 min of the life-time elapses, the etching quantity of the nitride film rises up to the vicinity of 5 nm. Thus, according to the semiconductor device manufacturing method in the embodiment, it can be understood that the etching quantity of the nitride film is restrained down to 1 nm or under even after the 2000-min elapse of the life-time.

### Modified Example

As described above, before inputting the sulfuric acid into the internal tank 121, the sulfuric acid is warmed up in the SPM preparatory tank 123. The sulfuric acid may, however, be inputted directly into the internal tank 121 without warming up the sulfuric acid in the SPM preparatory tank 123. In this case, the resist peeling process and the cleaning process of the semiconductor substrate 1 are executed by a device provided with none of the SPM preparatory tank 123.

<Others>

The disclosures of Japanese patent application No. JP2005-309769 filed on Oct. 25, 2005 including the specification, drawings and abstract are incorporated herein by reference.

What is claimed is:

1. A semiconductor device manufacturing method comprising:
heating up a solution containing sulfuric acid and hydrogen peroxide solution;
replenishing said solution with a predetermined quantity of sulfuric acid and a predetermined quantity of hydrogen peroxide solution at a predetermined interval;
maintaining a concentration of said sulfuric acid in said solution at a predetermined concentration level or higher; and
immersing a semiconductor substrate in said solution, and cleaning said semiconductor substrate.

2. A semiconductor device manufacturing method according to claim 1, wherein said cleaning includes removing impurities adhered on the surface of said semiconductor substrate.

3. A semiconductor device manufacturing method comprising:
forming a resist film on a semiconductor substrate;
forming a resist pattern on said resist film;
processing said semiconductor substrate in a way that uses said resist pattern as a mask;
heating up a solution containing sulfuric acid and hydrogen peroxide solution;
replenishing said solution with a predetermined quantity of sulfuric acid and a predetermined quantity of hydrogen peroxide solution at a predetermined interval;
maintaining a concentration of said sulfuric acid in said solution at a predetermined concentration level or higher; and
immersing said semiconductor substrate in said solution, and removing said resist pattern.

4. A semiconductor device manufacturing method according to claim 3, wherein said processing includes implanting ions into said semiconductor substrate.

5. A semiconductor device manufacturing method according to claim 1, wherein the predetermined concentration is 75.8% by mass.

6. A semiconductor device manufacturing method according to claim 1, wherein said sulfuric acid and said hydrogen peroxide solution ins aid solution are set at a predetermined volume ratio.

7. A semiconductor device manufacturing method according to claim 1, wherein the heating is effected at a predetermined temperature.

8. A semiconductor device manufacturing method according to claim 6, wherein the predetermined volume ratio is 4:1 through 100:1.

9. A semiconductor device manufacturing method according to claim 7, wherein the predetermined temperature is 100° C. through 140° C.
